(19) United States
(12) Patent Application Publication
(10) Pub. No.: US 2009/0243640 A1
(43) Pub. Date: Oct. 1, 2009

(54) CONDUCTIVE CONTACT PIN AND SEMICONDUCTOR TESTING EQUIPMENT

(75) Inventors: Nobuhiro Katsuma, Shiga (JP); Tomohiko Kanemitsu, Osaka (JP); Takashi Ogawa, Niigata (JP)

Correspondence Address: STEPTOE & JOHNSON LLP, 1330 CONNECTICUT AVE., NW, WASHINGTON, DC, 20036, US

(73) Assignee: Panasonic Corporation, Kadoma-shi (JP)

(21) Appl. No.: 12/409,965

(22) Filed: Mar. 24, 2009

(30) Foreign Application Priority Data
Mar. 28, 2008 (JP) 2008-085081

(51) Int. Cl. G01R 31/02

(52) U.S. Cl. 324/754

(57) ABSTRACT

In a conductive contact pin brought into contact with the external electrode of a semiconductor device to conduct a test on the electrical characteristics of the semiconductor device, an upper plunger 13 which is a contact pin coming in and out of a cylindrical body is made up of a base b which is in sliding contact with the cylindrical body and is not in contact with the external electrode and an end a which comes into contact with the external electrode. The base b has at least a surface layer made of a precious metal, and the end a has at least a surface layer made of one of a different metal from the base b and a metal alloy.

### FIELD OF THE INVENTION

The present invention relates to a conductive contact pin and semiconductor testing equipment which are used for measuring the electrical characteristics of a semiconductor device with a measuring device.

### BACKGROUND OF THE INVENTION

In tests on the electrical characteristics of semiconductor devices (semiconductor IC devices), semiconductor testing equipment is generally disposed between the semiconductor devices and measuring devices. In a kind of semiconductor testing equipment of the prior art, conductive contact pins of pogo pin type are used.

In semiconductor testing equipment shown in FIG. 6, conductive contact pins 10 of pogo pin type each include a coiled compression spring 12 and plungers 13 and 14 in a cylindrical body 11. The compression spring 12 urges the plunger 13 above the cylindrical body 11 and urges the other plunger 14 below the cylindrical body 11. Reference numeral 31 denotes a holder of the conductive contact pins 10 and reference numeral 32 denotes a test circuit board connected to a measuring device 40. The plungers 13 and 14 are also called contact pins.

In a test on a semiconductor device 51, the semiconductor testing equipment is disposed as illustrated and is relatively moved close to the semiconductor device 51. Thus the plungers 13 are pressed to external electrodes 52 of the semiconductor device 51 and the plungers 14 are pressed to lands 33 of the test circuit board 32, so that the external electrodes 52 and the lands 33 are electrically connected via the plungers 13 and 14 and the cylindrical body 11.

Generally, as shown in FIG. 7, the plunger 13 of the conductive contact pin 10 is formed of a metallic base material 20 of carbon tool steel, beryllium copper and so on into a predetermined shape, and the plunger 13 includes a hard Ni plating layer 21 for stabilizing the metal surface of the base material 20 and a Au plating layer 22 covering the Ni plating layer 21 to prevent oxidation (National Publication of International Patent Application No. 2004-503783).

When the conductive contact pins configured thus are used for testing the semiconductor device on which the external electrodes are formed of solder balls, as the number of tests increases, a Au—Sn alloy layer made of Sn (tin), which is a main component of solder, and Au (gold) contained in conductive contact terminals is formed on the ends of the conductive contact terminals (that is, the plungers energized in contact with the external electrodes). On the surface of the alloy layer, an oxide layer is formed by oxidation. As the number of tests further increases, solder is deposited on the alloy layer and the oxide layer is extendedly formed on the surface of the solder. As a result, a contact resistance value is destabilized and increases with the number of tests.

### DISCLOSURE OF THE INVENTION

In view of the foregoing problem, an object of the present invention is to provide a conductive contact pin and semiconductor testing equipment which can reduce the adhesion of an external electrode material when conducting tests on the electrical characteristics of a semiconductor device.

In order to attain the object, according to the present invention, a conductive contact pin having a contact pin coming in and out of a cylindrical body, the contact pin being brought into contact with the external electrode of a semiconductor device, the contact pin including a base which is in sliding contact with the cylindrical body and is not in contact with the external electrode and an end which comes into contact with the external electrode, the base having at least a surface layer made of a precious metal, the end having at least a surface layer made of one of a different metal from the base and a metal alloy.

Semiconductor testing equipment of the present invention includes conductive contact pins each of which has a contact pin coming in and out of a cylindrical body, the contact pin being brought into contact with the external electrode of a semiconductor device, the contact pin including a base which is in sliding contact with the cylindrical body and is not in contact with the external electrode and an end which comes into contact with the external electrode, the base having at least a surface layer made of a precious metal, the end having at least a surface layer made of one of a different metal from the base and a metal alloy.

With these configurations, the base of the contact pin is made of a precious metal, so that electrical stability can be achieved. Since the end is not made of a precious metal but is made of one of a different metal and a metal alloy, thereby suppressing the adhesion of generally used solder to the external electrode.

The precious metal of the base may be at least one selected from the group consisting of Au, Pt, and Ag. The one of the metal and the metal alloy of the end may be at least one selected from the group consisting of Ni, Co, and Cd.

The precious metal of the base may be at least one selected from the group consisting of Au, Pt, and Ag. The one of the metal and the metal alloy of the end may be at least one selected from a metal and a metal alloy which have a lower rate of dissolution in Sn than Pb.

The surface layer of the base may be a plating layer. The surface layers of the base and the end may be plating layers. At least one of the base and the end may be entirely made of the same material.

The semiconductor testing equipment may include a removing device for removing electrode chips generated from the external electrodes by the contact of the contact pins. The removing device may be a suction tool.

### BRIEF DESCRIPTION OF THE DRAWINGS

FIG. 1 is a sectional view showing a conductive contact pin according to an embodiment of the present invention;

FIG. 2 is a sectional view showing the contact portion of the conductive contact pin shown in FIG. 1;

FIG. 3 is a sectional view showing a modification of the contact portion of FIG. 2;

FIG. 4 is a sectional view showing another modification of the contact portion of FIG. 2;

FIG. 5 is a sectional view showing semiconductor testing equipment of the present invention, the semiconductor testing equipment including the conductive contact pins shown in FIG. 1;

FIG. 6 is a sectional view showing semiconductor testing equipment of the prior art; and

FIG. 7 is a sectional view showing the contact portion of a conductive contact pin included in the semiconductor testing equipment of FIG. 6.

### DESCRIPTION OF THE EMBODIMENTS

An embodiment of the present invention will be described below with reference to the accompanying drawings.

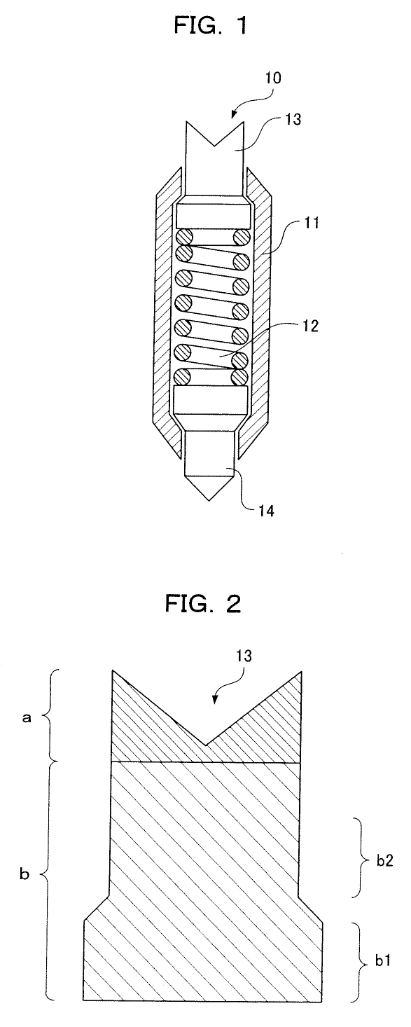

In FIG. 1, a conductive contact pin 10 is called pogo-pin type and is made up of a cylindrical body 11, a coiled compression spring 12, an upper plunger 13, and a lower plunger 14 which are disposed in the cylindrical body 11. The compression spring 12 urges the upper plunger 13 in a direction along which the end of the upper plunger 13 protrudes above the cylindrical body 11, and urges the lower plunger 14 in a direction along which the end of the lower plunger 14 protrudes below the cylindrical body 11.

The cylindrical body 11 and the lower plunger 14 are made of beryllium copper (may be made of low-carbon steel, both of the materials are relatively inexpensive with high machinability). The cylindrical body 11 and the lower plunger 14 are first plated with Ni and then are plated with Au such that Au plating covers Ni plating.

The upper plunger 13 is made up of, as shown in FIG. 2, an end a which comes into contact with the external electrode of a semiconductor device to be tested and a base b which comes into sliding contact with the cylindrical body 11 without coming into contact with the external electrode. The base b has a large diameter portion b1 and a small diameter portion b2 which are in sliding contact with the cylindrical body 11 and is made of a precious metal such as Au. The end a is made of a nonprecious metal (will be described later) such as Ni and has a crown-like protrusion formed by cutting thereon. One of the end a and the base b is mechanically fastened to the other by a technique such as press fitting (not shown).

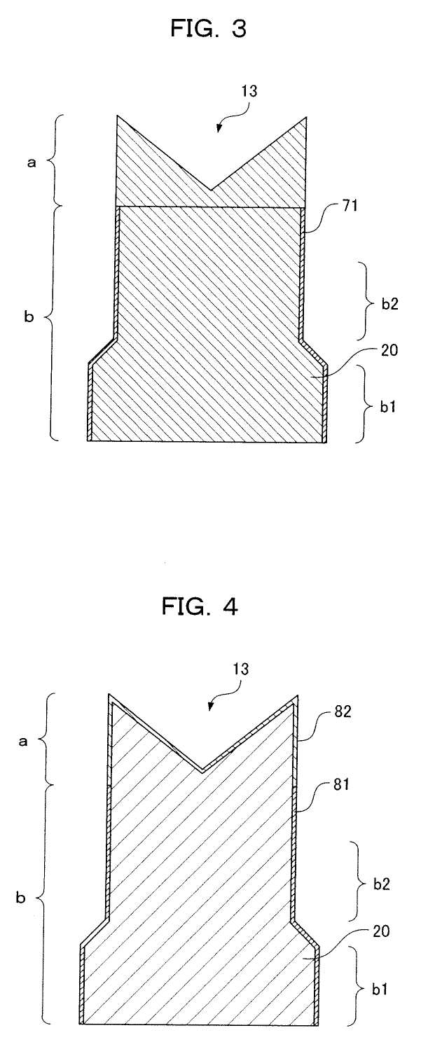

FIG. 3 shows a modification of the upper plunger 13. A base b of the upper plunger 13 is formed of a base material 20 of Ni. The base b has a Au plating layer 71 formed thereon. An end a is formed of Ni as the base material 20. The other configurations are the same as FIG. 2.

FIG. 4 shows another modification of the upper plunger 13. A base b and an end a of the upper plunger 13 are formed of a base material 20 of beryllium copper. The base b has a multilevel plating layer 81 formed thereon. The multilevel plating layer 81 is made up of a Ni plating layer and a Au plating layer covering the Ni plating layer. On the surface of the end a, a Ni plating layer 82 is formed. The Ni plating layer 82 has a thickness of about 1 μm to 2 μm. In the multilevel plating layer 81, the Ni plating layer has a thickness of about 1 μm to 2 μm and the Au plating layer has a thickness of about 0.1 μm to 0.3 μm. The other configurations are the same as the first embodiment.

The effects of the configurations will be described below. Since the surface of the end a of the upper plunger 13 is made of Ni, an alloy with tin contained in solder as a main component of the external electrode is hardly formed on a portion energized in contact with the external electrode. Since such an alloy is not formed, the adhesion of tin is extremely low on the end a and thus tin temporarily adhering to the end a easily falls off. For this reason, it is possible to suppress the deposition of tin on the end a and suppress the expanded formation of an oxide layer of tin on the surface of the end a. It is consequently possible to keep a stable contact resistance value even when the number of tests increases.

Generally, on Ni, an extremely thin oxide film of several angstroms is formed but the oxide film is quite brittle. The crown-like protrusion of the end a is sharply shaped and the contact load of the compression spring is applied when the end a comes into contact with the external electrode, so that even when an oxide film is formed on Ni of the end a, the oxide film can be sufficiently broken.

On the other hand, the large diameter portion b1 and the small diameter portion b2 are in surface contact with the cylindrical body 11 and structurally receive just a small contact load from the compression spring 12, so that it is not expected that an oxide film can be sufficiently removed. Thus the surface of the base b is made of a precious metal such as Au to eliminate the problem of an oxide film.

In other words, in the upper plunger 13, which is the single member, the base b which is in sliding contact with the cylindrical body 11 and is not in contact with the external electrode to be tested is made of a precious metal and the end a which comes into contact with the external electrode is not made of a precious metal but is made of one of a different metal and a metal alloy, so that the adhesion of solder is reduced and the electrical connection is stabilized.

The precious metal used for the base b may be at least one selected from the group consisting of Au, Pt, and Ag. A nonprecious metal used for the end a (one of a pure metal different from the precious metal and a metal alloy of the pure metal) may be at least one selected from the group consisting of Ni, Co, and Cd. An alloy of Ni and one of or both of Co and Cd may be used. These metals will be described below.

Generally, in a state in which a metal having a high ionization tendency and a metal having a low ionization tendency are in contact with each other, when water in the air and NaCl and the like in a use environment adhere to the metals and the metals are covered with electrolyte, a potential difference occurs between the contact portions of the metals, current passes from the metal having a low ionization tendency (noble metal) to the metal having a high ionization tendency (base metal), so that the base metal becomes a metal ion and corrosion is started (called bimetallic corrosion).

The corrosion is prevented by using, for the end a coming into contact with the external electrode, a base metal having an ionization tendency close to that of tin which is a main component of solder. Such base metals include Pb, Ni, Co, and Cd. Pb is not proper in view of recent environmental problems and thus Ni, Co, and Cd are preferable. However, the higher the Co and Cd contents, the ionization tendency becomes farther away from that of Sn. Thus the use of only Ni is more preferable. Precious metals usable for the base b not coming into contact with the external electrode include Au, Pt, Ag, and Hg. Although Au, Pt, and Ag are preferably used, the use of only Au is more preferable.

Alternatively, a precious metal used for the base b may be at least one selected from the group consisting of Au, Pt, and Ag. A nonprecious metal used for the end a (one of a pure metal different from the precious metal and a metal alloy of the pure metal) may be at least one of a metal and a metal alloy which have a lower rate of dissolution in Sn than Pb. These metals will be described below.

Generally, regarding the rates of dissolution of representative metals in tin, which is a main component of solder, a relationship of Pt, Ni<Pb<Cu<Ag<Au<Sn is established. For example, relative to 60 Sn-40 Pb solder, Sn has a dissolution rate of about 200 um/s, Au has a dissolution rate of about 10 um/s, and Pt and Ni have dissolution rates of about 0.01 um/s or less at 250° C. The metals having high dissolution rates are easily dispersed in tin and are likely to form alloys with tin. Once a tin alloy is formed, tin in solder is deposited on tin in the tin alloy in an accelerated manner, and an oxide layer is extendedly formed on the surface of the solder.

Thus for the end a coming into contact with the external electrode, metals having low rates of dissolution in Sn, particularly Ni and Pt having low rates of dissolution are used rather than Pb which is undesirable in view of environments, so that the extended formation of the oxide layer is prevented. Ni is more preferable in terms of cost. Precious metals usable for the base b not coming into contact with the external electrode include Au, Pt, Ag, and Hg. Although Au, Pt, and Ag are preferably used, the use of only Au is more preferable.

When the end a is plated with a thickness of 1 μm or less, pin holes are likely to occur and adversely affect a parent metal. When the end a is plated with a thickness of 5 μm or larger, an edge line for cutting becomes less sharp, so that the thickness of plating is preferably 1 μm to 5 μm depending upon the shape of the end a. The shape of the end a is not limited to the illustrated crown shape. The same effect can be obtained by a needle shape and a cup shape.

The base b has the Au plating layer 71, which is a precious metal plating layer, on the surface of the base material 20 (Ni), and the end a is formed integrally with or separately from the base material 20 (Ni) of the base b and is exposed as it is, so that the upper plunger 13 of FIG. 3 can be easily configured.

Further, the base b includes the multilevel plating layer 81 having the Au plating layer thereon and the end a only includes the Ni plating layer 82, so that the upper plunger 13 of FIG. 4 can be easily configured with the base material 20. For the base material 20, a relatively inexpensive material with high machinability can be used.

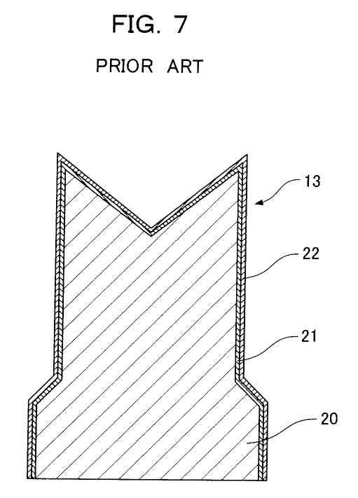

In order to obtain the upper plunger 13 of FIG. 4, for example, an existing plunger including a multilevel plating layer made up of a Ni plating layer and a Au plating layer may be used as has been illustrated in FIG. 7, or a manufacturing process of the plunger may be used.

For example, for the existing plunger, the Au plating layer is exfoliated or etched by a solution of cyan (mixed solution of NaCN+aqueous hydrogen peroxide), aqua regia (hydrochloric acid+nitric acid), acid (hydrochloric acid solution), iodine (iodine+alkaline iodide), and the like to expose the Ni plating layer; the end a is further plated with Ni; the end a is polished to expose the Ni plating layer; or the end a is plated with Au according to the manufacturing process of the existing plunger while the end a is masked to leave the Ni plating layer on the surface of the end a.

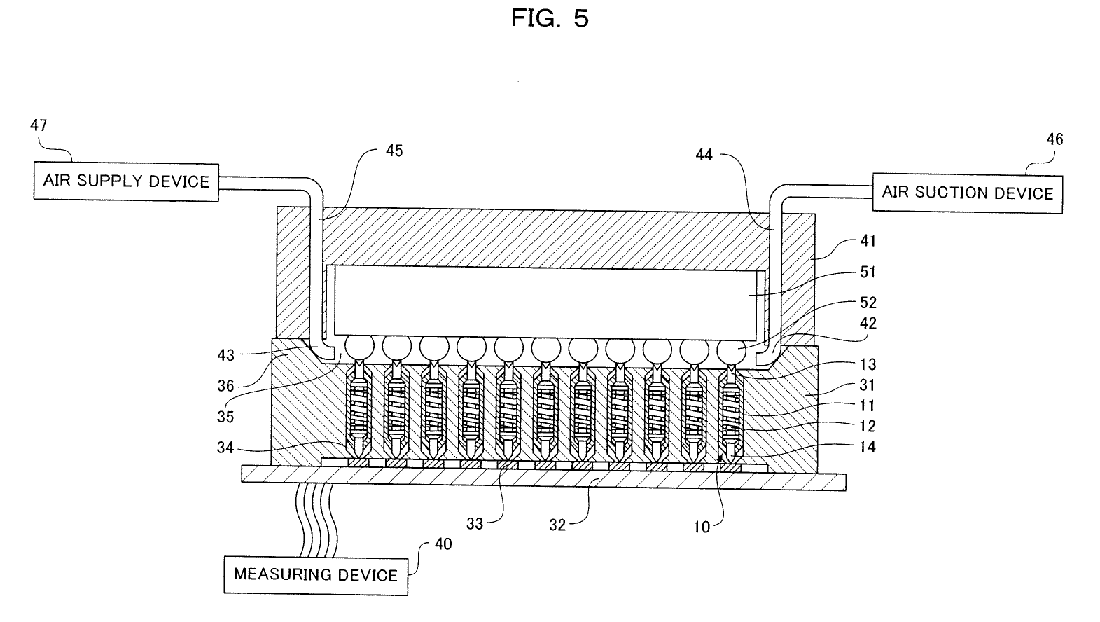

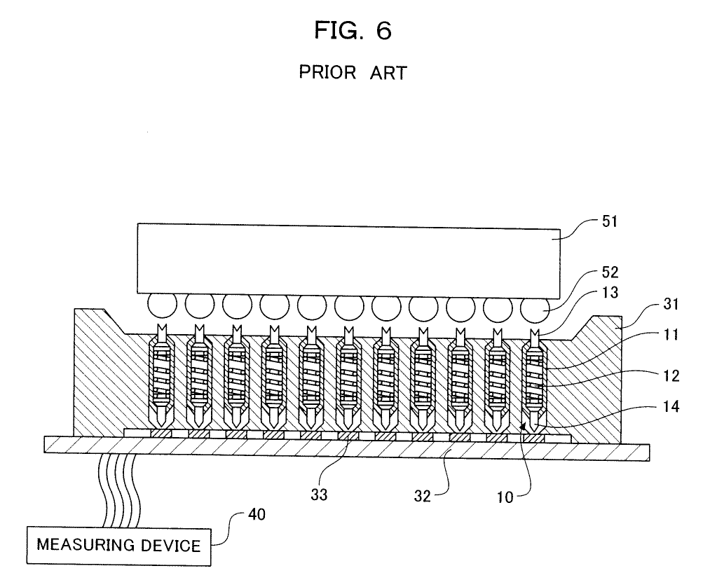

FIG. 5 is a sectional view showing semiconductor testing equipment having the conductive contact pins 10.

The semiconductor testing equipment includes the plurality of conductive contact pins 10, a holder 31 for holding the plurality of conductive contact pins 10, a test circuit board 32 having the holder 31 attached thereon, and a pressing frame 41 for pressing a semiconductor device 51 to the plurality of conductive contact pins 10 held by the holder 31.

The holder 31 has a plurality of holes 34 for aligning the plurality of conductive contact pins 10 with lands 33 of the test circuit board 32 in fixed directions so as to protrude the upper plungers 13, and the holder 31 has a step 36 on the outer edge, the step 36 forming a connection space 35 of the protruding upper plungers 13 and external electrodes 52 of the semiconductor device 51.

In this semiconductor testing equipment, when the semiconductor device 51 is mounted in the recessed portion of the pressing frame 41 and is pressed to the plurality of conductive contact pins 10, the compression springs 12 of the conductive contact pins 10 press the upper plungers 13 to the external electrodes 52 of the semiconductor device 51 and press the lower plungers 14 to the lands 33 of the test circuit board 32. Thus the external electrodes 52 and the lands 33 are electrically connected via the plungers 13 and 14 and the cylindrical bodies 11, allowing a measuring device 40 connected to the test circuit board 32 to perform measurements.

The configuration of the upper plunger 13 is effective as has been discussed. The end a of the upper plunger 13 is made of Ni, so that the adhesion of solder can be reduced. In this case, the adhesion of solder is not completely prevented but the solder falls off without being fixed on the end a. The falling solder may be left in the semiconductor testing equipment as chips and adhere to the semiconductor device 51 again.

For this reason, the semiconductor testing equipment includes air suction ports 42 for sucking solder chips and air intake ports 43 for blowing away solder chips. The air suction ports 42 and the air intake ports 43 are disposed so as to correspond to the four sides of the semiconductor device 51 (two of the sides are not shown). To be specific, an air suction path 44 and an air intake path 45 are provided in the pressing frame 41 so as to dispose the air suction ports 42 and the air intake ports 43 in the connection space 35 formed by the step 36 of the holder 31, an air suction device 46 is connected to the air suction path 44, and an air supply device 47 is connected to the air intake path 45.

With this configuration, when a load is applied to the semiconductor device 51 to conduct an electrical test as shown in FIG. 5, gas such as air is supplied through the air intake ports 43 and is sucked through the air suction ports 42, so that the flow path of the gas is limited and the gas can be prevented from being dispersed over the semiconductor testing equipment. When the gas is supplied with an insufficient amount and rate, solder chips may adhere to the semiconductor device 51. Thus it is necessary to quickly feed a large amount of gas.

The semiconductor testing equipment includes at least one of the air suction ports 42 and one of the air intake ports 43. The number of ports varies according to the size of the semiconductor device 51 and the number of the external electrodes 52. The single air intake port 43 may be provided for the three air suction ports 42, and vice versa.

As has been discussed, according to the conductive contact pin of the present invention, the base which is in sliding contact with the cylindrical body and is not in contact with the external electrode to be tested is made of a precious metal in the upper plunger (contact pin) which is the single member, thereby achieving electrical stability. Further, the end coming into contact with the external electrode is not made of a precious metal but is made of one of a different metal and a metal alloy, thereby suppressing the adhesion of the material of the external electrode and an increase in contact resistance.

Thus even when the conductive contact pins are repeatedly used for a long time, it is possible to achieve a stable electrical connection to the semiconductor device. It is further possible to reduce the number of times of cleaning for removing the adhering material of the external electrodes, thereby increasing the life of the semiconductor testing equipment. The semiconductor testing equipment having the conductive contact pins configured thus can reduce maintenance and replacing operations. This effect is noticeable when the semiconductor testing equipment includes a removing device for removing electrode chips generated from the external electrodes.

What is claimed is:

1. A conductive contact pin having a contact pin coming in and out of a cylindrical body, the contact pin being brought into contact with an external electrode of a semiconductor device, the contact pin including a base which is in sliding contact with the cylindrical body and is not in contact with the external electrode and an end which comes into contact with the external electrode, the base having at least a surface layer made of a precious metal, the end having at least a surface layer made of one of a different metal from the base and a metal alloy.

2. The conductive contact pin according to claim 1, wherein the precious metal of the base is at least one selected from the group consisting of Au, Pt, and Ag, and the one of the metal and the metal alloy of the end is at least one selected from the group consisting of Ni, Co, and Cd.

3. The conductive contact pin according to claim 1, wherein the precious metal of the base is at least one selected from the group consisting of Au, Pt, and Ag, and the one of the metal and the metal alloy of the end is at least one selected from a metal and a metal alloy which have a lower rate of dissolution in Sn than Pb.

4. The conductive contact pin according to claim 1, wherein the surface layer of the base is a plating layer.

5. The conductive contact pin according to claim 1, wherein the surface layers of the base and the end are plating layers.

6. The conductive contact pin according to claim 1, wherein at least one of the base and the end is entirely made of a same material.

7. Semiconductor testing equipment comprising conductive contact pins each of which has a contact pin coming in and out of a cylindrical body, the contact pin being brought into contact with an external electrode of a semiconductor device, the contact pin including a base which is in sliding contact with the cylindrical body and is not in contact with the external electrode and an end which comes into contact with the external electrode, the base having at least a surface layer made of a precious metal, the end having at least a surface layer made of one of a different metal from the base and a metal alloy.

8. The semiconductor testing equipment according to claim 7, further comprising a removing device for removing electrode chips generated from the external electrodes by contact of the contact pins.

9. The semiconductor testing equipment according to claim 7, wherein the removing device is a suction tool.
